(19) United States
(12) Patent Application Publication
(10) Pub. No.: US 2003/0183912 A1
(43) Pub. Date: Oct. 2, 2003

(54) Multi-chip package

(76) Inventor: Chung Hsien Hsin, Hsinchu Hsien (TW)

Correspondence Address: PRO-TECHTOR INTERNATIONAL, 20775 Norada Court, Saratoga, CA, 95070-3018, US

(21) Appl. No.: 10/097,820

(22) Filed: Mar. 13, 2002

(51) Int. Cl. H01L 23/02

(52) U.S. Cl. 257/678

(57) ABSTRACT

The invention relates to a multi-chip package capable of packaging a number of chips within a package and increasing the package capability. The multi-chip package includes a substrate, a frame layer, a plurality of chips, and a plurality of wires. The substrate includes an upper surface and a lower surface. The upper surface is formed with a plurality of first contact points, and the lower surface is formed with a plurality of second contact points. The frame layer is arranged under the lower surface of the substrate to form a chamber under the lower surface of the substrate. The frame layer is formed with a plurality of signal output terminals electrically connecting to the first and second contact points of the substrate. The plurality of chips are arranged on the upper surface of the substrate and the lower surface of the substrate. Some of the plurality of chips arranged on the lower surface are received within the chamber. The plurality of wires electrically connects the plurality of chips to the first and second contact points, respectively.

### BACKGROUND OF THE INVENTION

1. Field of the Invention

The invention relates to a multi-chip package, in particular, to a multi-chip package capable of effectively increasing the package capacity and facilitating the manufacturing processes.

2. Description of the Related Art

Referring to FIG. 1, a stacked structure for a conventional semiconductor chip includes a substrate 10, a lower semiconductor chip 12, an upper semiconductor chip 13 and a stopper 14. The substrate 10 includes an upper surface 16 and a lower surface 18. The upper surface 16 is formed with a plurality of first contact points 20 while the lower surface 18 is formed with a plurality of second contact points 22. A plurality of metallic balls 24 are electrically connected to the second contact points 22, respectively. The lower semiconductor chip 12 is arranged on or mounted to the upper surface 16 of the substrate 10 and is electrically connected to the first contact points 20 of the substrate 10 via a plurality of wires 26, respectively. The stopper 14 is provided on the lower semiconductor chip 12 through an adhesive layer 15. The upper semiconductor chip 13 is also provided on the stopper 14 through the adhesive layer 15. Thus, the plurality of wires 26 are free from being pressed and damaged by the upper semiconductor chip 13.

However, during the manufacturing processes of the stacked structure for this semiconductor chip, an additional stopper 14 has to be manufactured. Then, the stopper 14 is coated with the adhesive layer 15 and is adhered onto the lower semiconductor chip 12. Finally, the upper semiconductor chip 13 is adhered to the stopper 14. Accordingly, the manufacturing processes are complicated, and the overall package volume is too large to meet the requirements of a light, thin, short, and small package. In addition, the electrical connection distance from the lower semiconductor chip 12 or the upper semiconductor chip 13 to the substrate 10 is so long that the signal transmission effects may be deteriorated.

Referring to FIG. 2, a stacked structure for another conventional semiconductor chip includes a substrate 30, a lower semiconductor chip 32, and an upper semiconductor chip 34. The substrate 30 includes an upper surface 36 formed with a plurality of first contact points 40, and a lower surface 38 formed with a plurality of second contact points 42. A plurality of metallic balls 44 are electrically connected to the second contact points 42. The lower semiconductor chip 32 is arranged on the upper surface 36 of the substrate 30 and is electrically connected to the first contact points 40 of the substrate 30 via a plurality of wires 46. An adhesive layer 48 is coated on the lower semiconductor chip 32 to cover the plurality of wires 46. The upper semiconductor chip 34 is adhered to the lower semiconductor chip 32 through the adhesive layer 48, thereby forming a stacked structure for the semiconductor chip. Accordingly, the plurality of wires 46 are free from being pressed and damaged by the upper semiconductor chip 34.

However, in the stacked structure for the semiconductor chip, a thicker adhesive layer 48 has to be coated. Therefore, the overall package volume is too large to meet the requirements of a light, thin, short, and small package. In addition, the electrical connection distance from the lower semiconductor chip 32 or the upper semiconductor chip 34 to the substrate 30 is so long that the signal transmission effects may be deteriorated.

Moreover, the two kinds of stacked designs of semiconductor chips are only suitable for the semiconductor chips having bonding pads arranged at the periphery thereof, but not suitable for the semiconductor chips having bonding pads arranged at the central positions thereof.

In view of the above-mentioned problems, it is an important object of the invention to provide a multi-chip package capable of effectively increasing the package capacity and facilitating the manufacturing processes.

### SUMMARY OF THE INVENTION

It is therefore an object of the invention to provide a multi-chip package capable of packaging a number of chips within a package so as to increase the package capacity.

Another object of the invention is to provide a multi-chip package capable of reducing the thickness of the stacked structure and enabling the structure to be light, thin, short, and small.

Still another object of the invention is to provide a multi-chip package capable of arranging bonding pads of semiconductor chips at central positions.

To achieve the above-mentioned objects, the invention provides a multi-chip package. The multi-chip package includes a substrate, a frame layer, a plurality of chips, and a plurality of wires. The substrate includes an upper surface and a lower surface. The upper surface is formed with a plurality of first contact points, and the lower surface is formed with a plurality of second contact points. The frame layer is arranged under the lower surface of the substrate to form a chamber under the lower surface of the substrate. The frame layer is formed with a plurality of signal output terminals electrically connecting to the first and second contact points of the substrate. The plurality of chips are arranged on the upper surface of the substrate and the lower surface of the substrate. Some of the plurality of chips arranged on the lower surface are received within the chamber. The plurality of wires electrically connects the plurality of chips to the first and second contact points, respectively.

Accordingly, a number of chips can be received within a package so as to effectively increase the package capacity and facilitate the manufacturing processes.

### BRIEF DESCRIPTION OF THE DRAWINGS

FIG. 1 is a schematic illustration showing a stacked structure for a conventional semiconductor chip.

FIG. 2 is a schematic illustration showing another stacked structure for another conventional semiconductor chip.

FIG. 3 is a schematic illustration showing a multi-chip package in accordance with a first preferred embodiment of the invention.

FIG. 4 is a schematic illustration showing a multi-chip package in accordance with a second preferred embodiment of the invention.

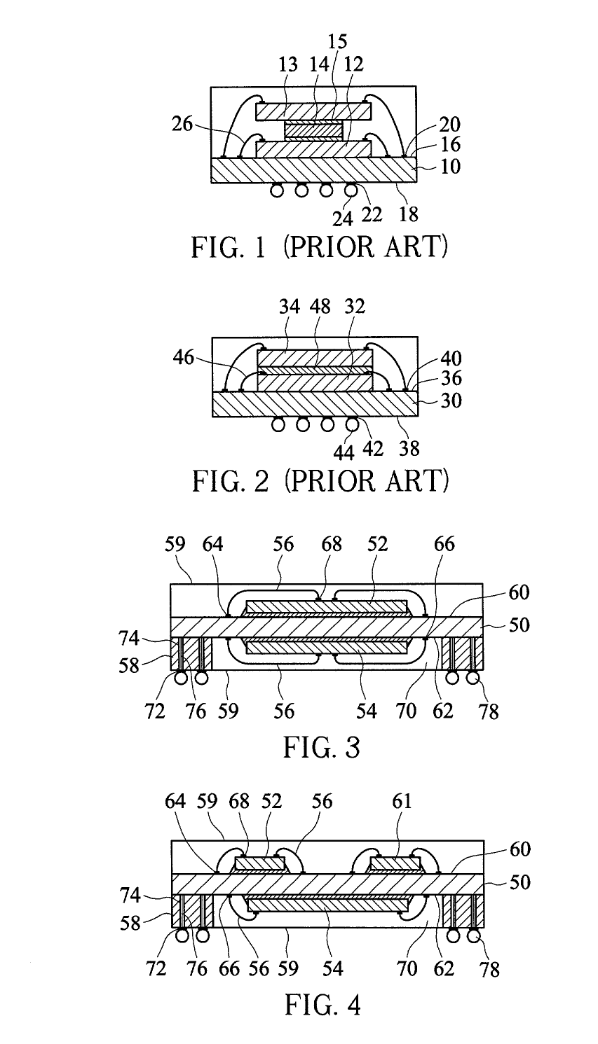

### DETAIL DESCRIPTION OF THE INVENTION

Referring to FIG. 3, a multi-chip package in accordance with a first preferred embodiment of the invention includes a substrate 50, a first chip 52, a second chip 54, a plurality of wires 56, a frame layer 58, glue 59, and a plurality of metallic balls 78.

The substrate 50 includes an upper surface 60 and a lower surface 62. The upper surface 60 is formed with a plurality of first contact points 64 while the lower surface 62 is formed with a plurality of second contact points 66.

The first chip 52 arranged on the upper surface 60 of the substrate 50 is formed with a plurality of bonding pads 68 at a central position thereof. The bonding pads 68 are electrically connected to the first contact points 64 of the substrate 50 via a plurality of wires 56 so that signals from the first chip 52 can be transmitted to the substrate 50.

The frame layer 58 is arranged under the lower surface 62 of the substrate 50 to form a chamber 70 under the lower surface 62. The frame layer 58 is formed with a plurality of signal output terminals 72. Also, the frame layer 58 is formed with through holes 74 in which wires 76 are provided. Therefore, the first and second contact points 64 and 66 of the substrate 50 can be electrically connected to the signal output terminals 72 via the wires 76 received within the through holes 74.

The second chip 54 is arranged within the chamber 70 under the lower surface 62 of the substrate 50, and is electrically connected to the second contact points 66 of the substrate 50 via the plurality of wires 56.

The glue 59 is provided to cover and pack the first and second chips 52 and 54 so as to protect the first and second chips 52 and 54 and the plurality of wires 56.

The plurality of metallic balls 78 are BGA (ball grid array) metallic balls arranged under the frame layer 58 attached to the lower surface of the substrate. The metallic balls 78 are also electrically connected to the signal output terminals 72, respectively.

Accordingly, by attaching the first and second chips 52 and 54 onto the upper surface 60 and the lower surface 62 of the substrate 10 respectively, it is possible to package two chips, each having bonding pads at its central portion, within one package. Thus, the package capacity can be increased. In addition, the manufacturing processes during stacking can be facilitated to lower the manufacturing costs. At the same time, the problem of unable to stack two chips, each having bonding pads at its central portion, can be solved.

Referring to FIG. 4, a multi-chip package in accordance with a second preferred embodiment of the invention includes a substrate 50, a first chip 52, a second chip 54, a third chip 61, a plurality of wires 56, a frame layer 58, glue 59, and a plurality of metallic balls 78.

The substrate 50 includes an upper surface 60 and a lower surface 62. The upper surface 60 is formed with a plurality of first contact points 64 while the lower surface 62 is formed with a plurality of second contact points 66.

The first chip 52 is formed with a plurality of bonding pads 68 at its peripheral position, and is arranged on the upper surface 60 of the substrate 50. The bonding pads 68 are electrically connected to the first contact points 64 of the substrate 50 via the plurality of wires 56 so that the signals from the first chip 52 can be transmitted to the substrate 50.

The third chip 61 is also arranged on the upper surface 60 of the substrate 50 in parallel with the first chip 52. Also, the third chip 61 is electrically connected to the first contact points 64 of the substrate 50 via the plurality of wires 56.

The frame layer 58 is arranged under the lower surface 62 of the substrate 50 to form a chamber 70 under the lower surface 62. The frame layer 58 is formed with a plurality of signal output terminals 72. Also, the frame layer 58 is formed with through holes 74 in which wires 76 are provided. Therefore, the first and second contact points 64 and 66 of the substrate 50 can be electrically connected to the signal output terminals 72 via the wires 76 received within the through holes 74.

The second chip 54 is arranged within the chamber 70 under the lower surface 62 of the substrate 50, and is electrically connected to the second contact points 66 of the substrate 50 via the plurality of wires 56.

The glue 59 is provided to cover and pack the first, second, and third chips 52, 54, and 61 so as to protect the first, second, and third chips 52, 54 and 61, and the plurality of wires 56.

The plurality of metallic balls 78 are BGA (ball grid array) metallic balls arranged under the frame layer 58 attached to the lower surface of the substrate. The metallic balls 78 are also electrically connected to the signal output terminals 72, respectively.

Accordingly, by attaching the first chip 52 and the second chips 54 onto the upper surface 60 of the substrate 10, and attaching the third chip 61 onto or under the lower surface 62 of the substrate 10, it is possible to package three chips within one package. Thus, the package capacity can be increased. In addition, the manufacturing processes during stacking can be facilitated to lower the manufacturing costs.

According to the preferred embodiments mentioned above, the multi-chip package of the invention has the following advantages.

1. A number of chips can be packaged within a package so that the package capacity can be increased and the manufacturing processes can be facilitated.

2. The thickness of the stacked package can be reduced so as to provide a light, thin, short, and small package.

3. The multi-chip package is suitable for the semiconductor chips having bonding pads arranged at the central positions thereof.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A multi-chip package, comprising:
a substrate including an upper surface and a lower surface, wherein the upper surface is formed with a plurality of first contact points, and the lower surface is formed with a plurality of second contact points;
a frame layer arranged under the lower surface of the substrate to form a chamber under the lower surface of the substrate, the frame layer being formed with a plurality of signal output terminals electrically connecting to the first and second contact points of the substrate;
a plurality of chips arranged on the upper surface of the substrate and the lower surface of the substrate, some of the plurality of chips arranged on the lower surface being received within the chamber; and
a plurality of wires for electrically connecting the plurality of chips to the first and second contact points, respectively.

2. The multi-chip package according to claim 1, wherein the frame layer is formed with through holes through which wires are provided to enable signals from the first and second contact points of the substrate to be transmitted to the signal output terminals.

3. The multi-chip package according to claim 1, further comprising glue for covering and protecting the plurality of chips and the plurality of wires.

4. The multi-chip package according to claim 1, further comprising:
a first chip arranged on the upper surface of the substrate; and
a second chip arranged under the lower surface of the substrate and received within the chamber under the lower surface.

5. The multi-chip package according to claim 1, further comprising:
a first chip and a second chip both arranged on the upper surface of the substrate; and
a third chip arranged under the lower surface and received within the chamber.

6. The multi-chip package according to claim 1, further comprising a plurality of metallic balls electrically connecting to the plurality of signal output terminals under the frame layer.

7. The multi-chip package according to claim 6, wherein the plurality of metallic balls are BGA metallic balls.
